(19) United States
(12) Patent Application Publication
(10) Pub. No.: US 2025/0255047 A1
(43) Pub. Date: Aug. 7, 2025

(54) DISPLAY DEVICE

(71) Applicant: LG Display Co., Ltd., Seoul (KR)

(72) Inventors: SeungJun LEE, Paju-si (KR); Kiyong YANG, Seoul (KR); YongSeok KWAK, Paju-si (KR)

(73) Assignee: LG Display Co., Ltd., Seoul (KR)

(21) Appl. No.: 18/764,994

(22) Filed: Jul. 5, 2024

(30) Foreign Application Priority Data
Feb. 5, 2024 (KR) 10-2024-0017687

(51) Int. Cl. H01L 33/44; H01L 25/075; H01L 33/38; H01L 33/40; H01L 33/62

(52) U.S. Cl. CPC H10H 20/84; H01L 25/0753; H10H 20/8312; H10H 20/835; H10H 20/857

(57) ABSTRACT

A display device in one example includes a substrate in which a plurality of sub-pixels is defined, and a plurality of reflective electrodes disposed on the substrate. The display device further includes a plurality of first light emitting diodes (LEDs) disposed on the plurality of reflective electrodes in each of the plurality of sub-pixels, and a second LED disposed on the plurality of reflective electrodes in each of the plurality of sub-pixels and being different from the plurality of first LEDs. In addition, the display device includes a first light scattering layer disposed on the plurality of first LEDs, and a second light scattering layer disposed on the second LED and separated from the first light scattering layer.

### CROSS-REFERENCE TO RELATED APPLICATIONS

This application claims priority to Korean Patent Application No. 10-2024-0017687 filed on Feb. 5, 2024, in the Korean Intellectual Property Office, the entire disclosure of which is hereby expressly incorporated by reference into the present application.

### BACKGROUND

### Field

The present disclosure relates to a display device, and more particularly, to a display device using a light emitting diode (LED).

### Discussion of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to include personal digital assistants as well as monitors of computers and televisions, and a display device with a large display area and a reduced volume and weight is being studied.

Further, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a display device with reduced process costs by transferring a repair LED only when a defect occurs.

Another object to be achieved by the present disclosure is to provide a display device in which a light extraction efficiency of a repair LED can be improved.

Yet another object to be achieved by the present disclosure is to provide a display device in which a luminance variation depending on a viewing angle can be reduced.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device comprises a substrate in which a plurality of sub-pixels is defined. The display device comprises a plurality of reflective electrodes disposed on the substrate. The display device comprises a plurality of first light emitting diodes (LEDs) disposed on the plurality of reflective electrodes in each of the plurality of sub-pixels. The display device comprises a second LED disposed on the plurality of reflective electrodes in each of the plurality of sub-pixels and different from the plurality of first LEDs. The display device comprises a first light scattering layer disposed on the plurality of first LEDs. The display device comprises a second light scattering layer disposed on the second LED and separated from the first light scattering layer.

Other detailed matters of various embodiments are included in the detailed description and the drawings.

According to the present disclosure, manufacturing costs of a display device can be reduced by transferring a repair LED only when a defect occurs in a specific sub-pixel.

According to the present disclosure, a light emission efficiency variation for each LED can be reduced by providing a different light scattering layer depending on the type of an LED.

According to the present disclosure, a light emission efficiency variation can be reduced and light emission efficiency can be improved by adjusting the shape of a light scattering layer which varies depending on the type of an LED.

According to the present disclosure, power consumption can be reduced by improving a light extraction efficiency of a repair LED.

According to the present disclosure, a repair process can be easily performed by adjusting the width of a repair LED.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration diagram of a display device according to an embodiment of the present disclosure;

FIG. 2 is a cross-sectional view of a sub-pixel of the display device according to an embodiment of the present disclosure;

FIG. 3A through FIG. 3D are plan views of a sub-pixel for explaining a repair process of the display device according to an embodiment of the present disclosure;

FIG. 4A through FIG. 4D are cross-sectional views of the sub-pixel for explaining the repair process of the display device according to an embodiment of the present disclosure;

FIG. 5 is a graph for explaining an effect of the display device according to an embodiment of the present disclosure;

FIG. 6 is a cross-sectional view of a display device according to another embodiment of the present disclosure; and

FIG. 7 is a cross-sectional view of a display device according to yet another embodiment of the present disclosure.

### DETAILED DESCRIPTION OF THE EMBODIMENTS

Advantages and characteristics of the present disclosure and a method of achieving the advantages and characteristics will be clear by referring to various embodiments described below in detail together with the accompanying drawings. However, the present disclosure is not limited to various embodiments disclosed herein but will be implemented in various forms. Various embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing various embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” encompasses all the meanings and coverages of the term “may”.

Hereinafter, a display device according to various embodiments of the present disclosure will be described in detail with reference to accompanying drawings. All the components of each display device according to all embodiments of the present disclosure are operatively coupled and configured.

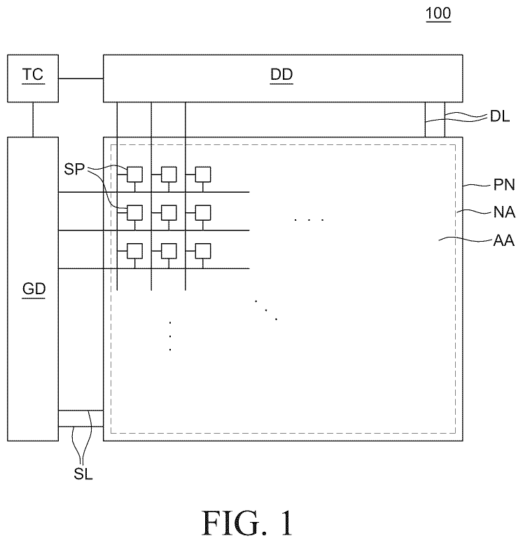

FIG. 1 is a schematic configuration diagram of a display device according to an embodiment of the present disclosure. FIG. 1 illustrates a display panel PN, a gate driver GD, a data driver DD, and a timing controller TC among various components of a display device 100 for the convenience of description.

Referring to FIG. 1, the display device 100 includes the display panel PN including a plurality of sub-pixels SP, and the gate driver GD and the data driver DD each configured to supply various signals to the display panel PN. Further, the display device 100 includes the timing controller TC configured to control the gate driver GD and the data driver DD.

The gate driver GD supplies a plurality of scan signals to a plurality of scan lines SL in response to a plurality of gate control signals supplied from the timing controller TC. FIG. 1 illustrates that one gate driver GD is disposed to be spaced apart from one side of the display panel PN. However, the number and disposition of gate drivers GD are not limited thereto.

The data driver DD converts image data input from the timing controller TC into a data voltage using a reference gamma voltage in response to a plurality of data control signals supplied from the timing controller TC. The data driver DD can supply the converted data voltage to a plurality of data lines DL.

The timing controller TC aligns image data input from the outside and supplies the image data to the data driver DD. The timing controller TC can generate the gate control signal and the data control signal using a synchronization signal input from the outside, e.g., a dot clock signal, a data enable signal, and a horizontal/vertical synchronization signal. Further, the timing controller TC can supply the generated gate control signal and data control signal to the gate driver GD and the data driver DD, respectively, to thereby control the gate driver GD and the data driver DD.

The display panel PN is configured to display images to a user, and includes the plurality of sub-pixels SP. In the display panel PN, the plurality of scan lines SL and the plurality of data lines DL intersect each other, and each of the plurality of sub-pixels SP is connected to the scan line SL and the data line DL. Each of the plurality of sub-pixels SP can be connected to a high potential power line, a low potential power line, a reference line, and the like.

In the display panel PN, a display area (or active area) AA and a non-display area (or non-active area0 NA enclosing the display area AA can be defined. The display area AA can be surrounded by the non-display area NA entirely or in part.

The display area AA is an area in which images are displayed in the display device 100. In the display area AA, the plurality of sub-pixels SP constituting a plurality of pixels and a circuit for driving the plurality of sub-pixels SP can be disposed. The plurality of sub-pixels SP can represent a minimum unit of the display area AA. Here, an N number of sub-pixels SP can form one pixel, where N can be, e.g., 3 or 4 but other variations are possible. In each sub-pixel SP, a light emitting device and a thin film transistor for driving the light emitting device can be disposed. The plurality of light emitting devices can be differently defined depending on the type of the display panel PN. For example, when the display panel PN is an inorganic light emitting display panel, the light emitting device can be a light emitting diode or a micro light emitting diode (micro LED).

In the display area AA, a plurality of signal lines for transmitting various signals to the plurality of sub-pixels SP is disposed. For example, the plurality of signal lines can include a plurality of data lines DL for supplying a data voltage to the plurality of sub-pixels SP, respectively. Further, the plurality of signal lines can include a plurality of scan lines SL for supplying a gate voltage to the plurality of sub-pixels SP, respectively. The plurality of scan lines SL can extend in one direction in the display area AA and can be connected to the plurality of sub-pixels SP. Further, the plurality of data lines DL can extend in a different direction from the one direction in the display area AA and can be connected to the plurality of sub-pixels SP. A low potential power line, a high potential power line, etc. can be further disposed in the display area AA. However, the present disclosure is not limited thereto.

The non-display area NA is an area in which no image is displayed, and can be defined as an area extending from the display area AA. In the non-display area NA, a link line and a pad electrode for transmitting signals to the sub-pixels SP disposed in the display area AA, and driver integrated circuit (ICs (such as a gate driver IC and a data driver IC can be disposed. The non-display area NA can be located on a rear surface of the display panel PN, i.e., a surface on which the sub-pixels SP are not disposed, or can be omitted and is not limited to the example illustrated in the drawing.

Meanwhile, a driving unit including the gate driver GD, the data driver DD, and the timing controller TC can be connected to the display panel PN in various ways. For example, the gate driver GD can be mounted in the non-display area NA as a GIP (Gate In Panel), or mounted between the plurality of sub-pixels SP in the display area AA as a GIA (Gate In Active area). For example, the data driver DD and the timing controller TC can be provided on a flexible film and a printed circuit board (printed circuit board). Further, the data driver DD and the timing controller TC can be electrically connected to the display panel PN by bonding the flexible film and the PCB to the pad electrode disposed in the non-display area NA of the display panel PN. The gate driver GD can be mounted as the GIP, and the data driver DD and the timing controller TC can transmit a signal to the display panel PN through the pad electrode disposed in the non-display area NA. In this case, the non-display area NA requires a space for placing the gate driver GD and the pad electrode, and, thus, a bezel can increase.

However, the gate driver GD can be mounted in the display area AA as the GIA, and a side line for connecting a signal line on a front surface of the display panel PN to the pad electrode on the rear surface of the display panel PN can be provided. Further, the flexible film and the PCB can be bonded to the rear surface of the display panel PN. In this case, the non-display area NA can be minimized on the front surface of the display panel PN. For example, when the gate driver GD, the data driver DD, and the timing controller TC are connected to the display panel PN as described above, a zero bezel can be implemented.

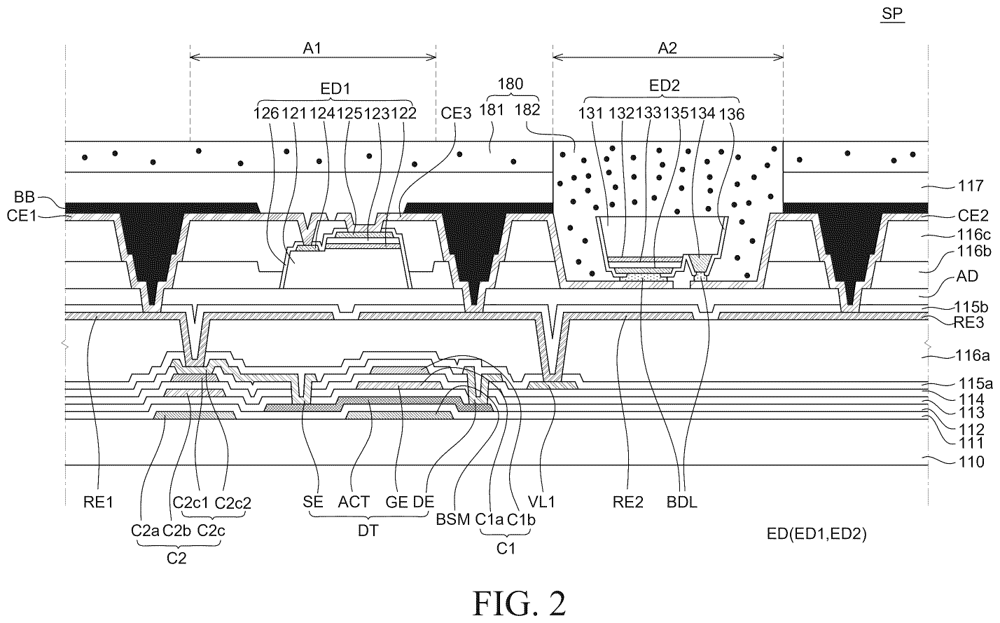

FIG. 2 is a cross-sectional view illustrating a sub-pixel of the display device according to an embodiment of the present disclosure.

Referring to FIG. 2, in each of the plurality of sub-pixels SP of the display device 100 according to an embodiment of the present disclosure, a light shielding layer BSM (e.g., bottom shield metal, etc.) and a driving transistor DT can be disposed. Further, in each of the plurality of sub-pixels SP, a first capacitor C1, a second capacitor C2, a first reflective electrode RE1, a second reflective electrode RE2, and a third reflective electrode RE3 can be disposed. Further, in each of the plurality of sub-pixels SP, a plurality of light emitting diodes (LEDs) ED, a first connection electrode CE1, a second connection electrode CE2, a third connection electrode CE3, and a plurality of bonding layers BDL can be disposed. Furthermore, in each of the plurality of sub-pixels SP, a plurality of power lines VL1, a bank BB, a protection layer 117, a first light scattering layer 181, and a second light scattering layer 182 can be disposed.

A plurality of inorganic insulating layers among insulating layers disposed on a substrate 110 can include a buffer layer 111, a gate insulating layer 112, and a first interlayer insulating layer 113. The plurality of inorganic insulating layers can further include a second interlayer insulating layer 114, a first passivation layer 115a, and a second passivation layer 115b.

Further, a plurality of organic insulating layers among the insulating layers disposed on the substrate 110 can include a first planarization layer 116a, an adhesive layer AD, a second planarization layer 116b, and a third planarization layer 116c.

First, the substrate 110 is configured to support various components included in the display device 100, and can be made of an insulating material. For example, the substrate 110 can be made of glass or resin. Further, the substrate 110 can contain a polymer or plastic, and can be made of a material having flexibility.

The light shielding layer BSM is disposed on the substrate 110. The light shielding layer BSM can serve to block light incident into an active layer ACT of a plurality of transistors and minimize a leakage current. For example, the light shielding layer BSM can be disposed under the active layer ACT of the driving transistor DT to block light incident into the active layer ACT. When light is irradiated to the active layer ACT, a leakage current can occur, and, thus, the reliability of the transistor can be degraded. Therefore, the light shielding layer BSM configured to block light can be disposed on the substrate 110 to improve the reliability of the driving transistor DT. The light shielding layer BSM can be made of an opaque conductive material, such as copper (Cu), aluminum (Al), molybdenum (Mo), nickel (Ni), titanium (Ti), chrome (Cr) or an alloy thereof, but is not limited thereto.

The buffer layer 111 is disposed on the light shielding layer BSM. The buffer layer 111 is an inorganic insulating layer which serves to suppress the permeation of moisture or impurities through the substrate 110. The buffer layer 111 can be configured by a single layer of silicon oxide (SiOx) or silicon nitride (SiNx) or a multi-layer thereof, but is not limited thereto. However, the buffer layer 111 can be omitted depending on the type of the substrate 110 or the type of the thin film transistor, but is not limited thereto.

The driving transistor DT including the active layer ACT, a gate electrode GE, a source electrode SE, and a drain electrode DE is disposed on the buffer layer 111.

An additional buffer layer can be disposed between the substrate 110 and the light shielding layer BSM. Like the buffer layer 111, the additional buffer layer is an inorganic insulating layer which serves to suppress the permeation of moisture or impurities through the substrate 110. The additional buffer layer can be configured by a single layer of, for example, silicon oxide (SiOx) or silicon nitride (SiNx) or a multi-layer thereof, but is not limited thereto.

First, the active layer ACT of the driving transistor DT is disposed on the buffer layer 111. The active layer ACT can be made of a semiconductor material, such as oxide semiconductor, amorphous silicon, or polycrystalline silicon, but is not limited thereto. Other transistors, such as a switching transistor, a sensing transistor, an emission control transistor, etc., besides the driving transistor DT can be further provided. Active layers of these transistors can also be made of semiconductor materials, such as oxide semiconductor, amorphous silicon, or polycrystalline silicon, but are not limited thereto. Further, the active layers of the transistors, such as the driving transistor DT, the switching transistor, the sensing transistor, the emission control transistor, etc., included in a pixel circuit can be made of the same material, or can be made of different materials from each other.

The gate insulating layer 112 is disposed on the active layer ACT. The gate insulating layer 112 is an inorganic insulating layer which serves to electrically insulate the active layer ACT from the gate electrode GE. The gate insulating layer 112 can be configured by a single layer of silicon oxide (SiOx) or silicon nitride (SiNx) or a multi-layer thereof, but is not limited thereto.

The gate electrode GE is disposed on the gate insulating layer 112. The gate electrode GE can be made of a conductive material, such as copper (Cu), aluminum (Al), molybdenum (Mo), nickel (Ni), titanium (Ti), chrome (Cr) or an alloy thereof, but is not limited thereto.

The first interlayer insulating layer 113 and the second interlayer insulating layer 114 are disposed on the gate electrode GE. The first interlayer insulating layer 113 and the second interlayer insulating layer 114 includes contact holes for connecting the source electrode SE and the drain electrode DE, respectively, to the active layer ACT. The first interlayer insulating layer 113 and the second interlayer insulating layer 114 are inorganic insulating layers which serve to protect the components disposed thereunder. Each of the first interlayer insulating layer 113 and the second interlayer insulating layer 114 can be configured by a single layer of silicon oxide (SiOx) or silicon nitride (SiNx) or a multi-layer thereof, but is not limited thereto.

The source electrode SE and the drain electrode DE electrically connected to the active layer ACT are disposed on the second interlayer insulating layer 114. The source electrode SE is connected to the second capacitor C2 and a first electrode 124, 134 of the LED ED, and the drain electrode DE is connected to another component of the pixel circuit. Each of the source electrode SE and the drain electrode DE can be made of a conductive material, such as copper (Cu), aluminum (Al), molybdenum (Mo), nickel (Ni), titanium (Ti), chrome (Cr) or an alloy thereof, but is not limited thereto.

The plurality of power lines VL1 is disposed on the second interlayer insulating layer 114. The plurality of power lines VL1 serves to transmit a power voltage to the LEDs ED of the plurality of sub-pixels SP, respectively. For example, the plurality of power lines VL1 can transmit a high potential power voltage or a low potential power voltage. Each of the plurality of power lines VL1 can be made of a conductive material, such as copper (Cu), aluminum (Al), molybdenum (Mo), nickel (Ni), titanium (Ti), chrome (Cr) or an alloy thereof, but is not limited thereto.

Then, the first capacitor C1 is disposed on the gate insulating layer 112. The first capacitor C1 includes a 1-1 capacitor electrode C1a and a 1-2 capacitor electrode C1b.

First, the 1-1 capacitor electrode C1a is disposed on the gate insulating layer 112. The 1-1 capacitor electrode C1a can be integrally formed with the gate electrode GE of the driving transistor DT.

The 1-2 capacitor electrode C1b is disposed on the first interlayer insulating layer 113. The 1-2 capacitor electrode C1b is disposed to overlap the 1-1 capacitor electrode C1a with the first interlayer insulating layer 113 interposed therebetween.

Thus, the first capacitor C1 can be connected to the gate electrode GE of the driving transistor DT to maintain a voltage of the gate electrode GE of the driving transistor DT for a predetermined period.

Then, the second capacitor C2 is disposed on the substrate 110. The second capacitor C2 includes a 2-1 capacitor electrode C2a, a 2-2 capacitor electrode C2b, and a 2-3 capacitor electrode C2c. The second capacitor C2 includes the 2-1 capacitor electrode C2a as a lower capacitor electrode, the 2-2 capacitor electrode C2b as an intermediate capacitor electrode, and the 2-3 capacitor electrode C2c as an upper capacitor electrode.

The 2-1 capacitor electrode C2a is disposed on the substrate 110. The 2-1 capacitor electrode C2a can be made of the same material and provided on the same layer as the light shielding layer BSM.

The 2-2 capacitor electrode C2b is disposed on the buffer layer 111 and the gate insulating layer 112. The 2-2 capacitor electrode C2b can be made of the same material and provided on the same layer as the gate electrode GE.

The 2-3 capacitor electrode C2c is disposed on the first interlayer insulating layer 113. The 2-3 capacitor electrode C2c can be composed of a first layer C2cl and a second layer C2c2. The first layer C2cl of the 2-3 capacitor electrode C2c can be formed of made of the same material and provided on the same layer as the 1-2 capacitor electrode C1b. The first layer C2cl can be disposed to overlap the 2-1 capacitor electrode C2a and the 2-2 capacitor electrode C2b with the first interlayer insulating layer 113 interposed therebetween.

The second layer C2c2 of the 2-3 capacitor electrode C2c is disposed on the second interlayer insulating layer 114. The second layer C2c2 is a portion extending from the source electrode SE of the driving transistor DT, and can be connected to the first layer C2cl through the contact hole of the second interlayer insulating layer 114.

Therefore, the second capacitor C2 can be electrically connected between the source electrode SE of the driving transistor DT and the LED ED. Thus, it is possible to increase a capacitance inherent in the LED ED and enable the LED ED to emit light with a higher luminance.

The first passivation layer 115a is disposed on the driving transistor DT, the first capacitor C1, and the second capacitor C2. The first passivation layer 115a is an inorganic insulating layer which serves to protect the components disposed thereunder. The first passivation layer 115a can be made of an inorganic material such as silicon oxide (SiOx) or silicon nitride (SiNx), but is not limited thereto.

The first planarization layer 116a is disposed on the first passivation layer 115a. The first planarization layer 116a can serve to planarize an upper portion of the pixel circuit including the driving transistor DT. The first planarization layer 116a can be configured by a single layer or a multi-layer, and can be made of, for example, benzocyclobutene or an acryl-based organic insulating layer, but is not limited thereto.

A plurality of reflective electrodes including the first reflective electrode RE1, the second reflective electrode RE2, and the third reflective electrode RE3 is disposed on the first planarization layer 116a. The first reflective electrode RE1, the second reflective electrode RE2, and the third reflective electrode RE3 can serve to electrically connect the plurality of LEDs ED to the plurality of power lines VL1 and the driving transistor DT. Further, the first reflective electrode RE1, the second reflective electrode RE2, and the third reflective electrode RE3 can serve as reflective sheets to reflect light emitted from the plurality of LEDs ED to above the substrate 110.

Each of the first reflective electrode RE1, the second reflective electrode RE2, and the third reflective electrode RE3 can be made of a conductive material having a high reflectivity. Further, each of the first reflective electrode RE1, the second reflective electrode RE2, and the third reflective electrode RE3 can reflect light emitted from the LED ED to above the LED ED.

The first reflective electrode RE1, the second reflective electrode RE2, and the third reflective electrode RE3 can include various conductive layers in consideration of light reflection efficiency and resistance. For example, the first reflective electrode RE1, the second reflective electrode RE2, and the third reflective electrode RE3 can include both an opaque conductive layer made of silver (Ag), aluminum (Al), molybdenum (Mo), titanium (Ti) or an alloy thereof and a transparent conductive layer made of indium tin oxide (ITO) or the like. However, the structure of the first reflective electrode RE1, the second reflective electrode RE2, and the third reflective electrode RE3 is not limited thereto.

The first reflective electrode RE1 can serve to reflect light emitted from the plurality of LEDs ED to above the first reflective electrode RE1.

The first reflective electrode RE1 can be connected to the source electrode SE or the drain electrode DE of the driving transistor DT through a contact hole formed in the first planarization layer 116a. Further, the first reflective electrode RE1 can be electrically connected to the plurality of LEDs ED. The first reflective electrode RE1 can be electrically connected to a first electrode 124 of a first LED ED1 through the first connection electrode CE1.

The second reflective electrode RE2 can serve to reflect light emitted from the LED ED to above the second reflective electrode RE2.

The second reflective electrode RE2 can electrically connect the plurality of power lines VL1 to the plurality of LEDs ED. The second reflective electrode RE2 can be electrically connected to the plurality of power lines VL1 through a contact hole formed in the first planarization layer 116a and the first passivation layer 115a. Further, the second reflective electrode RE2 can be electrically connected to the second electrode 125 of the first LED ED1 and a second electrode 135 of a second LED ED2 through the third connection electrode CE3.

The third reflective electrode RE3 can serve to reflect light emitted from the LED ED to above the third reflective electrode RE3.

The third reflective electrode RE3 can electrically connect the driving transistor DT to the plurality of LEDs ED. The third reflective electrode RE3 can be electrically connected to the first electrode 134 of the second LED ED2 through the second connection electrode CE2. Further, the third reflective electrode RE3 can be connected to the driving transistor DT through a contact hole formed in the first planarization layer 116a and the first passivation layer 115a. Thus, the third reflective electrode RE3 can electrically connect the second LED ED2 to the driving transistor DT.

Meanwhile, the first reflective electrode RE1 is separated from the third reflective electrode RE3. However, the present disclosure is not limited thereto. The first reflective electrode RE1 can be integrally formed with the third reflective electrode RE3.

Further, the first LED ED1 and the second LED ED2 can be driven by the same driving transistor DT, but the present disclosure is not limited thereto. The first LED ED1 and the second LED ED2 can be driven by different driving transistors DT.

Meanwhile, all of the plurality of LEDs ED can also be connected to the plurality of power lines VL1 without connection to the first reflective electrode RE1, the second reflective electrode RE2, and the third reflective electrode RE3. However, the present disclosure is not limited thereto.

The second passivation layer 115b is disposed on the first reflective electrode RE1, the second reflective electrode RE2, and the third reflective electrode RE3. The second passivation layer 115b is an inorganic insulating layer which serves to protect the components disposed thereunder. The second passivation layer 115b can be configured by a single layer of silicon oxide (SiOx) or silicon nitride (SiNx) or a multi-layer thereof, but is not limited thereto.

The second passivation layer 115b can include a plurality of contact holes for connecting the first connection electrode CE1, the second connection electrode CE2, and the third connection electrode CE3 to the first reflective electrode RE1, the second reflective electrode RE2, and the third reflective electrode RE3, respectively. Thus, upper surfaces of the first reflective electrode RE1, the second reflective electrode RE2, and the third reflective electrode RE3 can be exposed by the plurality of contact holes of the second passivation layer 115b.

The adhesive layer AD is disposed on the second passivation layer 115b. The adhesive layer AD can be provided on a front surface of the substrate 110 to fix the LED ED disposed on the adhesive layer AD. The adhesive layer AD can be configured as an organic insulating layer. The adhesive layer AD can be made of a photocurable adhesive material which is cured by light. For example, the adhesive layer AD can be made of an acryl-based material including a photosensitizer, but is not limited thereto.

The adhesive layer AD can planarize upper portions of the first reflective electrode RE1, the second reflective electrode RE2, and the third reflective electrode RE3. For example, the adhesive layer AD can cover a region among the first reflective electrode RE1, the second reflective electrode RE2, and the third reflective electrode RE3 which are spaced apart from each other. Further, the adhesive layer AD can planarize the upper portions of the first reflective electrode RE1, the second reflective electrode RE2, and the third reflective electrode RE3. However, the present disclosure is not limited thereto.

The adhesive layer AD can include a plurality of contact holes for connecting the first connection electrode CE1, the second connection electrode CE2, and the third connection electrode CE3 to the first reflective electrode RE1, the second reflective electrode RE2, and the third reflective electrode RE3, respectively. Thus, the upper surfaces of the first reflective electrode RE1, the second reflective electrode RE2, and the third reflective electrode RE3 can be exposed by the plurality of contact holes of the adhesive layer AD.

The plurality of LEDs ED is disposed on the adhesive layer AD in each of the plurality of sub-pixels SP.

The plurality of LEDs ED can include the first LED ED1 and the second LED ED2.

The first LED ED1 of the plurality of LEDs ED is disposed in a first area A1 in each of the plurality of sub-pixels SP.

The first LED ED1 is an LED which is transferred onto a substrate in an initial manufacturing process of a display device. For example, the first LED ED1 is disposed in each of the plurality of sub-pixels SP regardless of the presence or absence of a defect in the first LED ED1. Thus, the first LED ED1 can also be referred to as a main LED.

The first LED ED1 can include a first red LED, a first green LED, and a first blue LED.

Each of the first LEDs ED1 includes a first semiconductor layer 121, an emission layer 122, a second semiconductor layer 123, the first electrode 124, the second electrode 125, and an encapsulation film 126.

Hereinafter, the description will be made under the assumption that the first LED ED1 has a lateral structure, but the type of the first LED ED1 is not limited thereto.

The first semiconductor layer 121 of the first LED ED1 is disposed on the adhesive layer AD, and the second semiconductor layer 123 is disposed on the first semiconductor layer 121. Each of the first semiconductor layer 121 and the second semiconductor layer 123 can be formed by doping a specific material with n-type or p-type impurities. For example, each of the first semiconductor layer 121 and the second semiconductor layer 123 can be formed by doping a material, such as gallium nitride (GaN), indium aluminum phosphide (InAlP), or gallium arsenide (GaAs), with n-type or p-type impurities. The p-type impurities can be magnesium (Mg), zinc (Zn), beryllium (Be), or the like, and the n-type impurities can be silicon (Si), germanium (Ge), tin (Sn), or the like. However, the present disclosure is not limited thereto.

The emission layer 122 is disposed between the first semiconductor layer 121 and the second semiconductor layer 123. The emission layer 122 can emit light when supplied with holes and electrons from the first semiconductor layer 121 and the second semiconductor layer 123. The emission layer 122 can be configured by a single layer or a multi-quantum well (MQW) structure and made of, for example, indium gallium nitride (InGaN) or gallium nitride (GaN), but is not limited thereto.

The emission layer 122 and the second semiconductor layer 123 of the first LED ED1 can protrude above an upper surface of the first semiconductor layer 121.

The first electrode 124 of the first LED ED1 is disposed on the first semiconductor layer 121. The first electrode 124 serves to electrically connect the driving transistor DT to the first semiconductor layer 121. In this case, the first semiconductor layer 121 can be a semiconductor layer doped with n-type impurities, and the first electrode 124 can be a cathode. The first electrode 124 can be disposed on the upper surface of the first semiconductor layer 121 exposed from the emission layer 122 and the second semiconductor layer 123.

The first electrode 124 can be made of a conductive material, for example, a transparent conductive material, such as indium tin oxide (ITO) or indium zinc oxide (IZO), or an opaque conductive material, such as titanium (Ti), gold (Au), silver (Ag), copper (Cu) or an alloy thereof, but is not limited thereto.

The second electrode 125 of the first LED ED1 is disposed on the second semiconductor layer 123. The second electrode 125 can be in contact with an upper surface of the second semiconductor layer 123. The second electrode 125 serves to electrically connect the plurality of power lines VL1 to the second semiconductor layer 123. In this case, the second semiconductor layer 123 can be a semiconductor layer doped with p-type impurities, and the second electrode 125 can be an anode.

The second electrode 125 can be made of a conductive material, for example, a transparent conductive material, such as indium tin oxide (ITO) or indium zinc oxide (IZO), or an opaque conductive material, such as titanium (Ti), gold (Au), silver (Ag), copper (Cu) or an alloy thereof, but is not limited thereto.

Then, the encapsulation film 126 is disposed to enclose the first semiconductor layer 121, the emission layer 122, the second semiconductor layer 123, the first electrode 124, and the second electrode 125. The encapsulation film 126 is made of an insulating material and can serve to protect the first semiconductor layer 121, the emission layer 122, and the second semiconductor layer 123. Further, the encapsulation film 126 includes contact holes for exposing the first electrode 124 and the second electrode 125. Thus, the encapsulation film 126 can electrically connect the first connection electrode CE1 and the third connection electrode CE3 to the first electrode 124 and the second electrode 125.

Thereafter, the second planarization layer 116b and the third planarization layer 116c are disposed on the adhesive layer AD.

The second planarization layer 116b can be disposed to enclose a side portion of the first LED ED1 in the first area A1 and thus can fix and protect the first LED ED1. For example, the second planarization layer 116b can be disposed to enclose a lower side surface of the first LED ED1 in the first area A1.

The second planarization layer 116b can be configured by a single layer or a multi-layer, and can be made of, for example, benzocyclobutene or an acryl-based organic insulating layer. The second planarization layer 116b can be prepared by using a halftone mask. A portion of the second planarization layer 116b disposed more adjacent to the first LED ED1 can be formed to have a smaller thickness. Further, a portion of the second planarization layer 116b disposed farther from the first LED ED1 can be formed to have a greater thickness.

The second planarization layer 116b can cover a side surface of the first LED ED1 to suppress a contact failure and a short-circuit between the first and third connection electrodes CE1 and CE3 and the first LED ED1.

The second planarization layer 116b can include a plurality of contact holes for connecting the first connection electrode CE1, the second connection electrode CE2, and the third connection electrode CE3 to the first reflective electrode RE1, the second reflective electrode RE2, and the third reflective electrode RE3, respectively. Thus, the upper surfaces of the first reflective electrode RE1, the second reflective electrode RE2, and the third reflective electrode RE3 can be exposed by the plurality of contact holes of the second planarization layer 116b.

The third planarization layer 116c can cover upper portions of the second planarization layer 116b and the first LED ED1 in the first area A1.

The third planarization layer 116c can be configured by a single layer or a multi-layer, and can be made of, for example, photo resist or an acryl-based organic insulating material.

Meanwhile, the second planarization layer 116b and the third planarization layer 116c may not be disposed in a second area A2. For example, the second planarization layer 116b and the third planarization layer 116c can be disposed in the plurality of sub-pixels SP except the second area A2, but are not limited thereto.

The first connection electrode CE1, the second connection electrode CE2, and the third connection electrode CE3 can be disposed on the third planarization layer 116c.

The first connection electrode CE1 can connect the first LED ED1 to a plurality of first reflective electrodes RE1 in the first area A1. Further, the first connection electrode CE1 can electrically connect the first LED ED1 to a plurality of driving transistors DT.

The second connection electrode CE2 can electrically connect the second LED ED2 to the plurality of driving transistors DT in the second area A2.

The third connection electrode CE3 connects the first LED ED1 to the second LED ED2 in the first area A1 and the second area A2, and can be electrically connected to the second reflective electrode RE2. Further, the third connection electrode CE3 can electrically connect the power line VL1 to the first LED ED1 and the second LED ED2 in one sub-pixel SP.

Each of the first connection electrode CE1, the second connection electrode CE2, and the third connection electrode CE3 can be made of a transparent conductive material, such as indium tin oxide (ITO) or indium zinc oxide (IZO), but is not limited thereto.

Meanwhile, the first connection electrode CE1 and the first reflective electrode RE1 are electrically connected to the source electrode SE of the driving transistor DT. However, the third connection electrode CE3 and the second reflective electrode RE2 can also be connected to the drain electrode DE of the driving transistor DT, but are not limited thereto.

Each of the first connection electrode CE1, the second connection electrode CE2, and the third connection electrode CE3 can be disposed to have a step along a surface of an insulating layer disposed thereunder. For example, the first connection electrode CE1 can be disposed flat along a surface of the third planarization layer 116c in the first area A1. Further, each of the second connection electrode CE2 and the third connection electrode CE3 can be disposed along a surface of the adhesive layer AD in the second area A2. Thus, a distance from the first connection electrode CE1 to the substrate 110 in the first area A1 can be greater than a distance from the second connection electrode CE2 and the third connection electrode CE3 to the substrate 110 in the second area A2.

Further, the second connection electrode CE2 and the third connection electrode CE3 can cover side surfaces of the second planarization layer 116b and the third planarization layer 116c in the second area A2.

The bank BB is disposed on the first connection electrode CE1, the second connection electrode CE2, and the third connection electrode CE3. The bank BB can be made of an opaque material to suppress color mixture between the plurality of sub-pixels SP. For example, the bank BB can be made of black resin, but is not limited thereto.

The bank BB can be disposed to be spaced apart from the plurality of LEDs ED by a predetermined interval. At least a part of the bank BB can overlap the first reflective electrode RE1, the second reflective electrode RE2, and the third reflective electrode RE3.

The bank BB can include an opening corresponding to the second area A2. Thus, the bank BB may not overlap the first light scattering layer 181 disposed in the first area A1, and may not overlap the second light scattering layer 182 disposed in the second area A2.

The opening of the bank BB can overlap the second LED ED2. The bank BB can enclose a side portion of the second LED ED2 in the second area A2.

The plurality of bonding layers BDL is disposed on the second connection electrode CE2 and the third connection electrode CE3 in the second area A2. The plurality of bonding layers BDL can serve to fix the second LED ED2 onto the substrate 110.

The plurality of bonding layers BDL can be disposed in the second area A2 in each of the plurality of sub-pixels SP. The plurality of bonding layers BDL is disposed on the second connection electrode CE2 and the third connection electrode CE3 exposed by the bank BB.

The plurality of bonding layers BDL can be disposed to overlap the second LED ED2 of the plurality of LEDs ED. Herein, lower surfaces of the plurality of bonding layers BDL can be in contact with the second connection electrode CE2 and the third connection electrode CE3. Further, upper surfaces of the plurality of bonding layers BDL can be in contact with the first electrode 134 and a second electrode 135 of the second LED ED2. Thus, the plurality of bonding layers BDL can be connected to the first electrode 134 and a first semiconductor layer 131 of the second LED ED2 to electrically connect the second LED ED2 to the driving transistor DT. Further, the plurality of bonding layers BDL can be connected to the second electrode 135 and a second semiconductor layer 133 of the second LED ED2 to electrically connect the plurality of power lines VL1.

The plurality of bonding layers BDL can be made of a conductive material. Further, the plurality of bonding layers BDL can be made of a material having reflectivity. For example, the plurality of bonding layers BDL can be made of silver (Ag) or a silver (Ag) alloy, but is not limited thereto. Further, the plurality of bonding layers BDL can be made of one of silver (Ag) paste, aluminum (Al) paste, gold (Au) paste, and copper (Cu) paste. Alternatively, the plurality of bonding layers BDL can be made of silver (Ag), aluminum (Al), molybdenum (Mo), titanium (Ti) or an alloy thereof, but is not limited thereto.

The second LED ED2 is disposed on the plurality of bonding layers BDL.

The second LED ED2 is disposed in at least one of the plurality of sub-pixels SP. The second LED ED2 can be disposed in the second area A2 in the sub-pixel SP.

The second LED ED2 is an LED which is transferred onto the substrate 110 when the first LED ED1 disposed in the corresponding sub-pixel is defective. Thus, the second LED ED2 can also be referred to as a repair LED. Therefore, the second LED ED2 can be a normal LED (e.g., non-defective LED), and the first LED ED1 disposed in the same sub-pixel as the second LED ED2 can be a defective LED.

For example, when the first red LED of the first LED ED1 is defective, a second red LED can be disposed in the same sub-pixel as the first red LED. Thus, a second green LED and a second blue LED may not be disposed in the same sub-pixel in which the normal first green and blue LEDs are disposed. However, the present disclosure is not limited thereto. When the first green LED is defective, the second green LED can be disposed in the same sub-pixel as the first green LED. Further, when the first blue LED is defective, the second blue LED can be disposed in the same sub-pixel as the first blue LED.

The second LED ED2 includes the first semiconductor layer 131, an emission layer 132, the second semiconductor layer 133, the first electrode 134, the second electrode 135, and an encapsulation film 136.

The second semiconductor layer 133 of the second LED ED2 is disposed on the second connection electrode CE2, the third connection electrode CE3, and the plurality of bonding layers BDL. Further, the first semiconductor layer 131 of the second LED ED2 is disposed on the second semiconductor layer 133. Each of the first semiconductor layer 131 and the second semiconductor layer 133 can be formed by doping a specific material with n-type or p-type impurities. For example, each of the first semiconductor layer 131 and the second semiconductor layer 133 can be formed by doping a material, such as gallium nitride (GaN), indium aluminum phosphide (InAlP), or gallium arsenide (GaAs), with n-type or p-type impurities. The p-type impurities can be magnesium (Mg), zinc (Zn), beryllium (Be), or the like, and the n-type impurities can be silicon (Si), germanium (Ge), tin (Sn), or the like. However, the present disclosure is not limited thereto.

The emission layer 132 of the second LED ED2 is disposed between the first semiconductor layer 131 and the second semiconductor layer 133. The emission layer 132 can emit light when supplied with holes and electrons from the first semiconductor layer 131 and the second semiconductor layer 133. The emission layer 132 can be configured by a single layer or a multi-quantum well (MQW) structure and made of, for example, indium gallium nitride (InGaN) or gallium nitride (GaN), but is not limited thereto.

The emission layer 132 and the second semiconductor layer 133 of the second LED ED2 can protrude below a lower surface of the first semiconductor layer 131.

The first electrode 134 of the second LED ED2 is disposed under the first semiconductor layer 131. The first electrode 134 serves to electrically connect the driving transistor DT to the first semiconductor layer 131. In this case, the first semiconductor layer 131 can be a semiconductor layer doped with n-type impurities, and the first electrode 134 can be a cathode.

The first electrode 134 can be made of a conductive material, for example, a transparent conductive material, such as indium tin oxide (ITO) or indium zinc oxide (IZO), or an opaque conductive material, such as titanium (Ti), gold (Au), silver (Ag), copper (Cu) or an alloy thereof, but is not limited thereto.

The second electrode 135 of the second LED ED2 is disposed under the second semiconductor layer 133. The second electrode 135 can be in contact with the second semiconductor layer 133. The second electrode 135 serves to electrically connect the plurality of power lines VL1 to the second semiconductor layer 133.

The second electrode 135 can be made of a conductive material, for example, a transparent conductive material, such as indium tin oxide (ITO) or indium zinc oxide (IZO), or an opaque conductive material, such as titanium (Ti), gold (Au), silver (Ag), copper (Cu) or an alloy thereof, but is not limited thereto.

Then, the encapsulation film 136 is disposed to enclose the first semiconductor layer 131, the emission layer 132, the second semiconductor layer 133, the first electrode 134, and the second electrode 135. The encapsulation film 136 is made of an insulating material and can serve to protect the first semiconductor layer 131, the emission layer 132, and the second semiconductor layer 133. Further, the encapsulation film 136 includes contact holes for exposing the first electrode 134 and the second electrode 135. Thus, the encapsulation film 136 can electrically connect the plurality of bonding layers BDL to the first electrode 134 and the second electrode 135.

The second LED ED2 can have the same configuration as the first LED ED1, and a lamination order of the second LED ED2 can be opposite to that of the first LED ED1. For example, the first LED ED1 can be a lateral LED, and the second LED ED2 can be a flip-chip type LED.

The protection layer 117 is disposed on the first connection electrode CE1, the second connection electrode CE2, the third connection electrode CE3, and the bank BB. The protection layer 117 serves to protect the components disposed thereunder. The protection layer 117 can be configured by a single layer or a multi-layer, and can be made of, for example, benzocyclobutene, transparent epoxy, photo resist, or an acryl-based organic material, but is not limited thereto.

The protection layer 117 can be disposed to overlap at least some of the plurality of LEDs ED. For example, the protection layer 117 can be disposed in the first area A1 so as to overlap only the first LED ED1 among the plurality of LEDs ED.

Meanwhile, the protection layer 117 can include an opening corresponding to the second area A2. The opening of the protection layer 117 can overlap the opening of the bank BB. For example, in the opening of the protection layer 117, a side surface of the protection layer 117 can be disposed on the same plane as a side surface of the bank BB. However, the present disclosure is not limited thereto.

Alight scattering layer 180 can be disposed on the protection layer 117.

The light scattering layer 180 can be made of an organic material in which light scattering particles are dispersed. For example, each of the first light scattering layer 181 and the second light scattering layer 182 can be made of photo resist, an acryl-based organic material, or transparent epoxy in which light scattering particles are dispersed.

The light scattering particle can be a nano-sized spherical inorganic oxide particle having light scattering properties. The light scattering particle can be one of, for example, a titanium dioxide (TiO₂) particle, a silicon dioxide (SiO₂) particle, a zinc oxide (ZnO) particle, and an aluminum oxide (AlO₄) particle, but is not limited thereto. Further, the light scattering particle can be spherical, porous or a fibrous shape, but is not limited thereto.

The light scattering layer 180 can include the first light scattering layer 181 and the second light scattering layer 182.

The first light scattering layer 181 can be disposed in the other area than the second area A2. Thus, the first light scattering layer 181 can be disposed to be spaced apart from the first LED ED1 and the first connection electrode CE1, and can be disposed along a flat upper surface of the protection layer 117.

The first light scattering layer 181 can be disposed in all areas except the second area A2. Thus, the first light scattering layer 181 can be made of a low viscosity material so as to be evenly distributed in a large area.

Further, the first light scattering layer 181 can be made of a thermosetting material. Thus, the first light scattering layer 181 disposed in a large area can be cured on the substrate 110.

The second light scattering layer 182 can be disposed in the second area A2 and have different properties from the first light scattering layer 181.

The second light scattering layer 182 can fill in the opening of the protection layer 117 and the opening of the bank BB in the second area A2. Further, the second light scattering layer 182 can cover the second LED ED2 disposed in the second area A2 to fix and protect the second LED ED2. Further, the second light scattering layer 182 can be in contact with a side surface of the bank BB and a side surface of the first light scattering layer 181, but is not limited thereto.

The second light scattering layer 182 can cover the second LED ED2 and parts of the second connection electrode CE2 and the third connection electrode CE3 disposed under the second LED ED2.

The second light scattering layer 182 can contain a material having a different viscosity from the first light scattering layer 181. For example, the second light scattering layer 182 can have a higher viscosity than the first light scattering layer 181. The second light scattering layer 182 is disposed only in the second area A2 and disposed only in the opening of the protection layer 117 and the opening of the bank BB. Thus, the second light scattering layer 182 can be made of a high viscosity material so as to be disposed only in a local area.

Further, the second light scattering layer 182 can be made of a UV-curable material. For example, the second light scattering layer 182 can contain a photoinitiator which can cause UV (ultraviolet) polymerization. Thus, a UV laser is selectively irradiated only to the second area A2 in which the second light scattering layer 182 is disposed among all the areas on the substrate 110 to cure the second light scattering layer 182. Further, the time required for curing the second light scattering layer 182 can be reduced.

Meanwhile, the number of light scattering particles dispersed in the second light scattering layer 182 per unit area can be greater than the number of light scattering particles dispersed in the first light scattering layer 181 per unit area. For example, the number of light scattering particles dispersed in the second light scattering layer 182 per unit area can be greater by about 10% to about 20% than that of light scattering particles dispersed in the first light scattering layer 181 per unit area. For example, when the light scattering particles dispersed in the first light scattering layer per unit area 181 account for 10 wt %, the light scattering particles dispersed in the second light scattering layer per unit area 182 can account for 20 wt % to 30 wt %.

The first light scattering layer 181 can have a different transmittance from the second light scattering layer 182 due to a difference in number of light scattering particles between the first light scattering layer 181 and the second light scattering layer 182. For example, the transmittance of the first light scattering layer 181 in which a smaller number of light scattering particles are dispersed can be higher than the transmittance of the second light scattering layer 182. Further, the transmittance of the second light scattering layer 182 in which a greater number of light scattering particles are dispersed can be lower than the transmittance of the first light scattering layer 181.

Further, the first light scattering layer 181 can have a different refractive index from the second light scattering layer 182. For example, the second light scattering layer 182 can have a higher refractive index than the first light scattering layer 181. When the second LED ED2 is a micro LED, the second LED ED2 can have a higher luminance in a lateral direction than in a front direction. Thus, the second LED ED2 can have a luminance variation depending on a viewing angle. To reduce the luminance variation of the second LED ED2 depending on the viewing angle, the second light scattering layer 182 can contain a material having a relatively high refractive index.

An optical film can be disposed on the entire surface of the substrate 110 so as to cover upper portions of the first light scattering layer 181 and the second light scattering layer 182. The optical film can be a functional film to protect the display device 100 and realize images with higher quality. For example, the optical film can include an anti-scattering film, an anti-glare film, an anti-reflecting film, a low-reflecting film, an OLED transmittance controllable film, or a polarizing plate, but is not limited thereto.

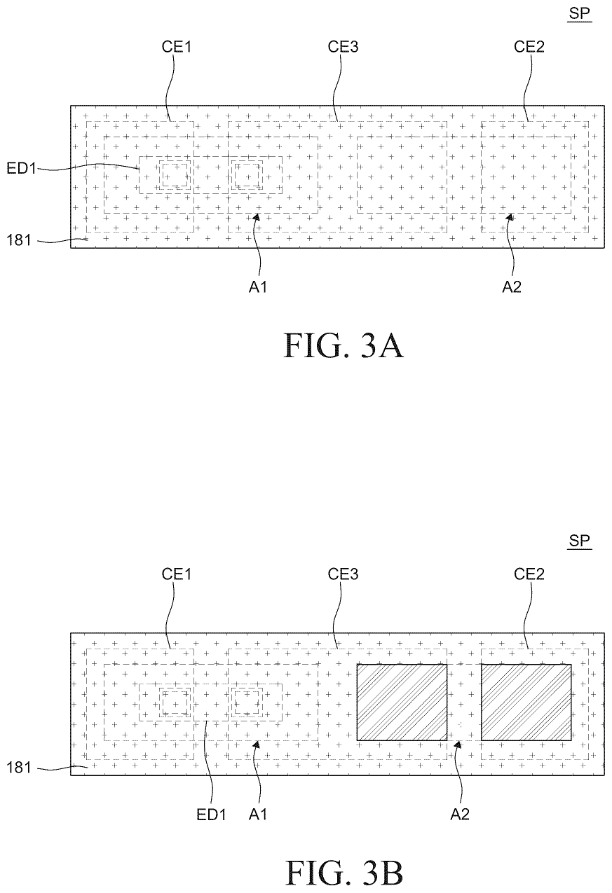

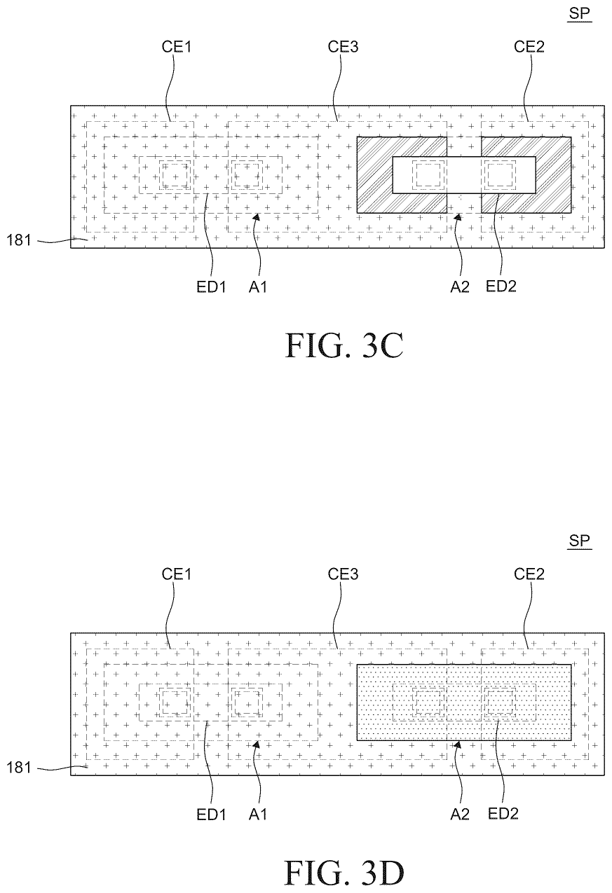

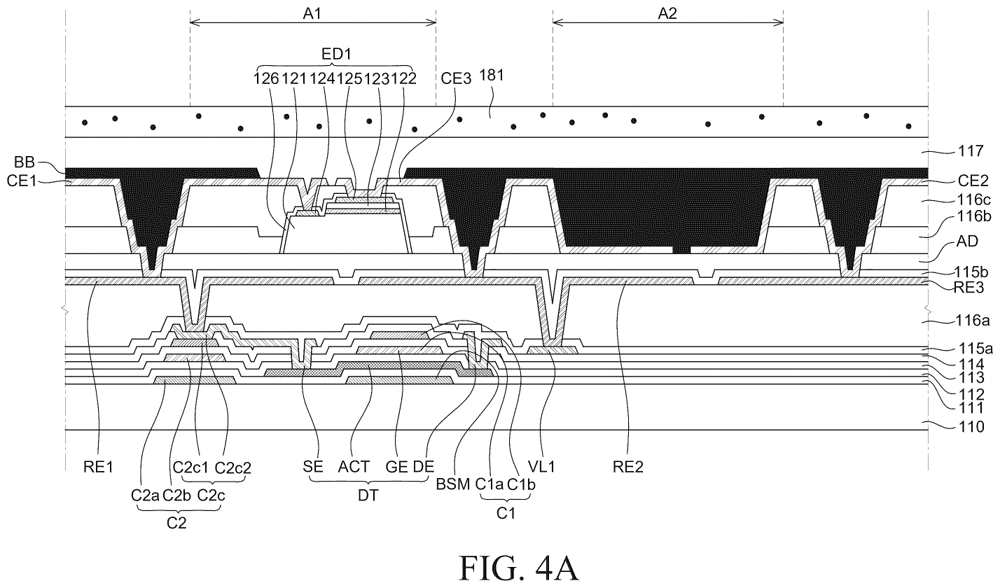

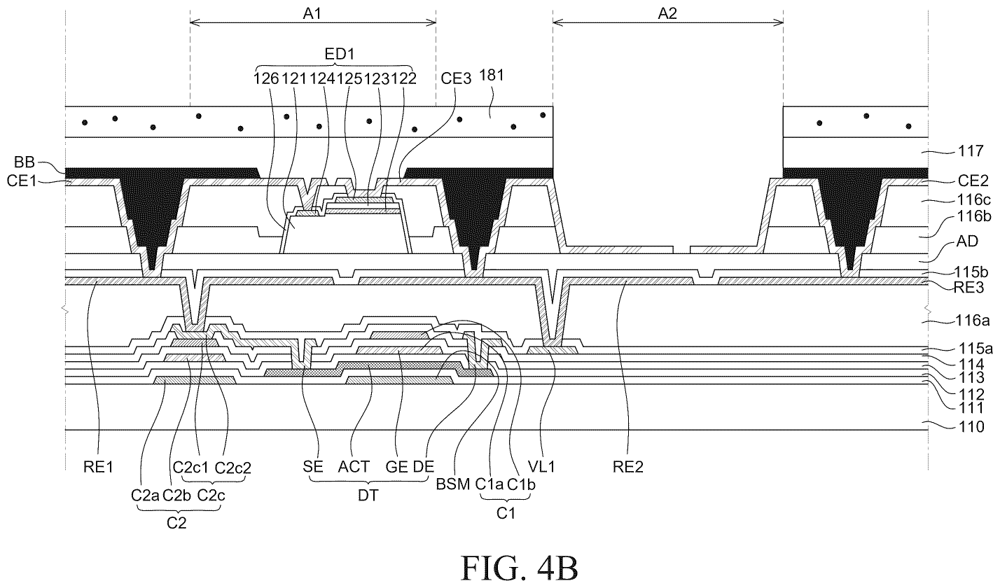

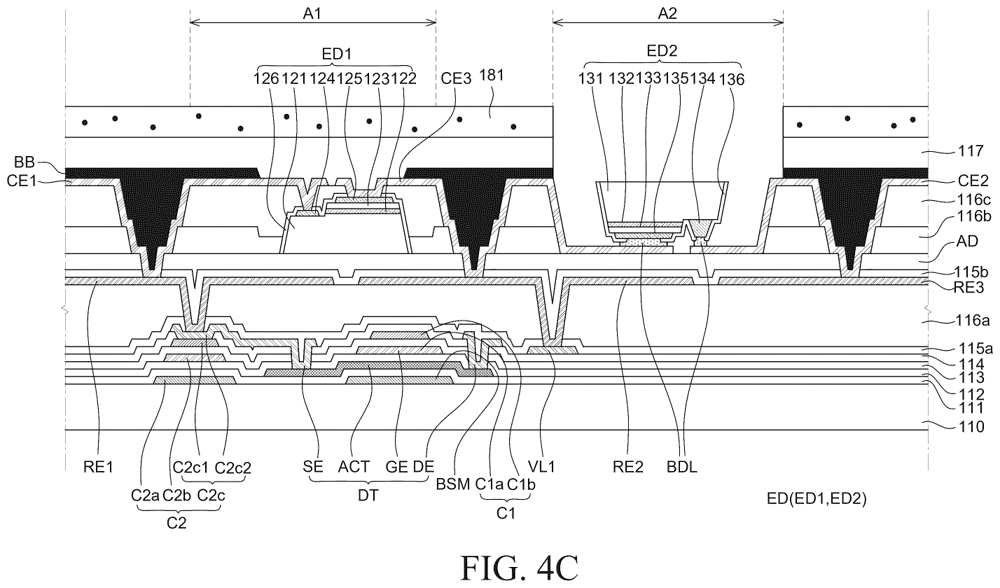

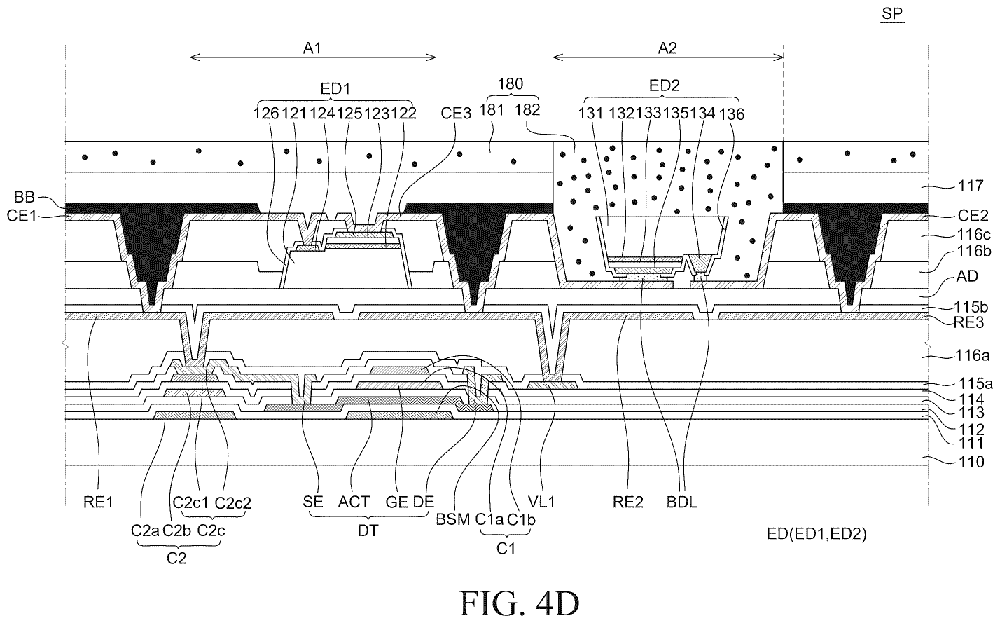

Hereinafter, a repair process of the display device according to an embodiment of the present disclosure will be described in detail with reference to FIG. 3A through FIG. 4D.

FIG. 3A through FIG. 3D are plan views of a sub-pixel for explaining the repair process of the display device according to an embodiment of the present disclosure. FIG. 4A through FIG. 4D are cross-sectional views of the sub-pixel for explaining the repair process of the display device according to an embodiment of the present disclosure. Particularly, FIG. 4A is a cross-sectional view of FIG. 3A, FIG. 4B is a cross-sectional view of FIG. 3B, FIG. 4C is a cross-sectional view of FIG. 3C, and FIG. 4D is a cross-sectional view of FIG. 3D.

Referring to FIG. 3A and FIG. 4A, each sub-pixel SP includes the first area A1 and the second area A2.

The first LED ED1 is disposed in the first area A1 of the sub-pixel SP, but the second LED ED2 is not disposed in the second area A2.

The first connection electrode CE1, the second connection electrode CE2 and the third connection electrode CE3, the bank BB, and the first light scattering layer 181 are sequentially provided on the first LED ED1.

Referring to FIG. 4A, the first connection electrode CE1 and the third connection electrode CE3 are provided on the first LED ED1 in the first area A1. Further, the second connection electrode CE2 and the third connection electrode CE3 cover an upper portion of the adhesive layer AD in the second area A2.

Referring to FIG. 3A and FIG. 4A, the bank BB and the first light scattering layer 181 are provided on the first connection electrode CE1, the second connection electrode CE2, and the third connection electrode CE3 in the entire first area A1 and second area A2.

Then, a lighting test is performed to the first LED ED1 disposed in the first area A1 of the plurality of sub-pixels SP, and any defective sub-pixel SP is repaired.

Referring to FIG. 3B and FIG. 4B, the bank BB, the protection layer 117 and the first light scattering layer 181 are removed to form an opening in the second area A2 of the defective sub-pixel SP. For example, the bank BB, the protection layer 117 and the first light scattering layer 181 disposed in the second area A2 can be removed through a laser process. Herein, the laser process can be performed to a greater width than the width of the second LED ED2 to be disposed in the second area A2. In the opening, parts of upper surfaces the second connection electrode CE2 and the third connection electrode CE3 corresponding in area to the second LED ED2 can be exposed.

Then, a bonding layer BDL is provided on the exposed second connection electrode CE2 and third connection electrode CE3, and the second LED ED2, which is a repair LED, is transferred onto the bonding layer BDL.

Referring to FIG. 4C, the bonding layer BDL is disposed on the second connection electrode CE2 and the third connection electrode CE3 in the second area A2.

The bonding layer BDL can be made of one of, for example, metal organic ion ink, metal nanoparticle ink, and metal nanoparticle paste.

Referring to FIG. 3C and FIG. 4C, the second LED ED2 is transferred onto the bonding layer BDL. The second LED ED2 can be locally transferred by using a stamp, but is not limited thereto.

The second semiconductor layer 133 of the second LED ED2 is disposed under the first semiconductor layer 131. Herein, the second electrode 135 of the second LED ED2 is electrically connected to the bonding layer BDL disposed on the third connection electrode CE3. Further, the first electrode 134 of the second LED ED2 is electrically connected to the bonding layer BDL disposed on the second connection electrode CE2.

Then, referring to FIG. 3D and FIG. 4D, the second light scattering layer 182 is coated on the second LED ED2.

The second light scattering layer 182 is provided to cover the second LED ED2 and upper portions of the second connection electrode CE2 and the third connection electrode CE3 in the second area A2.

Then, the second LED ED2 is fixed in the second area A2 through a curing process.

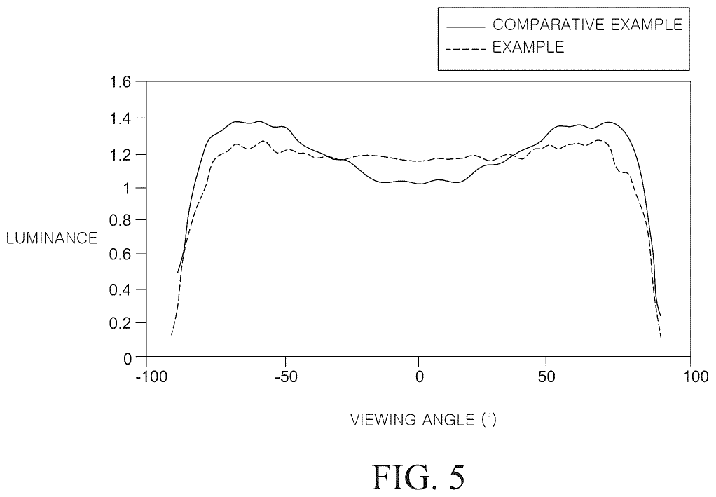

FIG. 5 is a graph for explaining an effect of the display device according to an embodiment of the present disclosure. Here, FIG. 5 shows an example of a graph for explaining a luminance distribution depending on a viewing angle according to Comparative Example and Example of the present disclosure. For instance, Example in FIG. 5 corresponds to the display device 100 according to an embodiment of the present disclosure. Comparative Example of FIG. 5 is different from Example in that the second insulating scattering layer 182 is not disposed. In the graph of FIG. 5, the X-axis represents a viewing angle and the Y-axis represents a luminance. Herein, the graph of FIG. 5 shows relative luminance based on a central luminance of 1 in Comparative Example.

Referring to FIG. 5, the luminance is higher in the lateral direction than in the front direction and highest at about 600 in Comparative Example and Example.

The central luminance of Comparative Example is 1 and the central luminance of Example is about 1.2. Therefore, it can be seen that the central luminance of the display device according to an embodiment of the present disclosure is improved by about 20%, as compared to that of Comparative Example.

Further, the maximum luminance of Comparative Example is about 1.25 and the maximum luminance of Example is about 1.35. Therefore, it can be seen that the maximum luminance of the display device according to an embodiment of the present disclosure is improved by about 8%, as compared to that of Comparative Example.

Furthermore, a variation between the central luminance and the maximum luminance of Comparative Example is about 0.25 and a variation between the central luminance and the maximum luminance of Example is about 0.15. Therefore, it can be seen that the variation between the central luminance and the maximum luminance of the display device according to an embodiment of the present disclosure is reduced by about 40%, as compared to that of Comparative Example.

In general, a plurality of sub-pixels disposed on a substrate can include a defective sub-pixel which does not emit light normally or properly. Thus, after a lighting test in a display device, a second LED which emits light of the same color as a defective first LED is transferred only onto a sub-pixel in which the defective first LED is detected. For example, after the lighting test, repair is locally performed through a laser process.

Meanwhile, a light scattering layer is disposed at an upper portion of the display device to improve a light extraction efficiency. In order to transfer the second LED onto the defective sub-pixel after the lighting test, the light scattering layer disposed is removed in a repair region together with a bank. Then, the second LED is transferred onto a region from which the light scattering layer and the bank are removed. Thereafter, an insulating layer made of a transparent material is provided on the second LED to fix and protect the second LED. If the second LED is transferred onto the region from which the light scattering layer is removed, the light scattering layer is not disposed on the second LED. Thus, the second LED has a lower light extraction efficiency than the first LED.

Thus, in the display device 100 according to an embodiment of the present disclosure, the first light scattering layer 181 is disposed on the first LED ED1. Further, the second light scattering layer 182 is provided on the second LED ED2 disposed in a region from which the first light scattering layer 181 is removed. Therefore, light emitted from the second LED ED2 is scattered by the second light scattering layer 182, and, thus, a light extraction efficiency of the second LED ED2 can be improved.

Further, the display device 100 according to an embodiment of the present disclosure includes the second light scattering layer 182 containing a material having a higher viscosity than the first light scattering layer 181. The second light scattering layer 182 is disposed only in the second area A2, which is a repair region, and disposed only in a defective sub-pixel SP among the plurality of sub-pixels SP. Thus, it is possible to suppress the overflow and excessive coating of the second light scattering layer 182 onto the first area A1 of its adjacent sub-pixel SP when the second light scattering layer 182 is made of a low viscosity material.

In general, the first LED disposed in the display device is a lateral type LED. Thus, the display device is designed to improve light extraction of the lateral type LED. For example, a light extraction pattern can be disposed on a lower surface of the first LED, and the display device can be designed to enable light refracted by the light extraction pattern to proceed to above the display device. Therefore, if a flip-chip type LED is transferred as the second LED, the second LED disposed in the repair region can have a lower light extraction efficiency than the first LED disposed in the normal sub-pixel. Further, the second LED can have a severe variation depending on the viewing angle.

Thus, in the display device 100 according to an embodiment of the present disclosure, the second light scattering layer 182 having different properties from the first light scattering layer 181 is disposed. This is to improve a light extraction efficiency of the second LED ED2. For example, if a flip-chip type LED is transferred as the second LED ED2, the second LED ED2 can have a lower light extraction efficiency than the first LED ED1. Thus, a greater number of light scattering particles are dispersed in the second light scattering layer 182 than in the first light scattering layer 181, and it is possible to improve the light extraction efficiency of the second LED ED2. Therefore, in the display device 100 according to an embodiment of the present disclosure, the luminance can be improved and, thus, the power consumption of the display device 100 can be reduced.

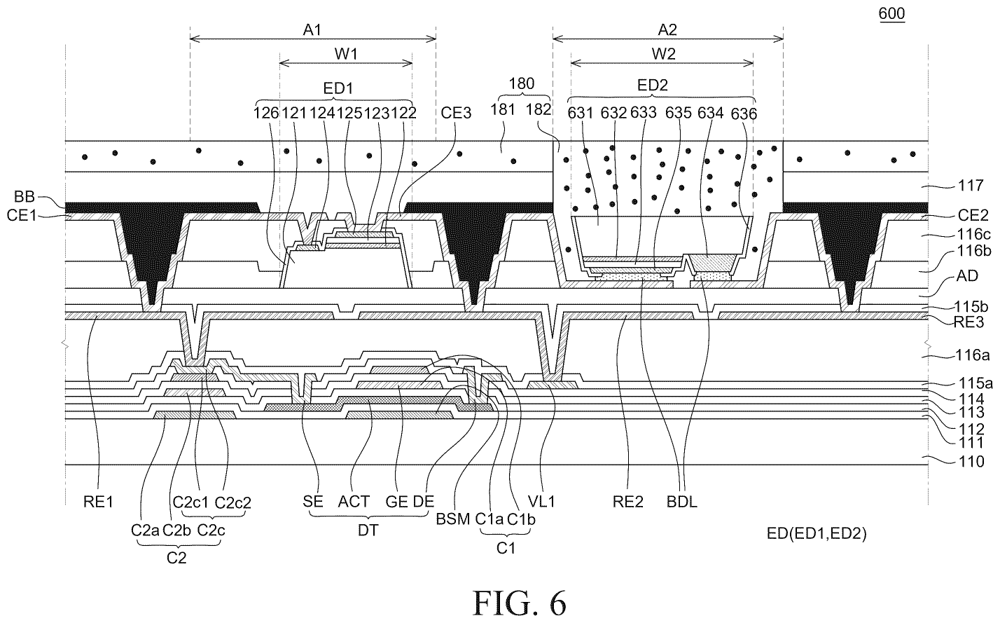

FIG. 6 is a cross-sectional view of a display device according to another embodiment of the present disclosure.

A display device 600 shown in FIG. 6 is substantially the same as the display device 100 shown in FIG. 1 through FIG. 5, except the second LED ED2. Therefore, a redundant description will be omitted or may be briefly mentioned.

Referring to FIG. 6, the second LED ED2 is disposed in the second area A2.

The second LED ED2 includes a first semiconductor layer 631, an emission layer 632, a second semiconductor layer 633, a first electrode 634, a second electrode 635, and an encapsulation film 636.

The second LED ED2 can have a greater width than that of a plurality of first LEDs ED1. The first semiconductor layer 631, the emission layer 632, the second semiconductor layer 633, the first electrode 634, the second electrode 635, and the encapsulation film 636 in each of the second LED ED2 can be respectively greater in width than the first semiconductor layer 121, the emission layer 122, the second semiconductor layer 123, the first electrode 124, the second electrode 125, and the encapsulation film 126 in the first LED ED1.

The second LED ED2 overlapping the substrate 110 can have a greater maximum width than that of the first LED ED1 overlapping the substrate 110. For example, a lower surface of the first semiconductor layer 121 of the first LED ED1 can have a first width W1. Further, an upper surface of the first semiconductor layer 631 of the second LED ED2 can have a second width W2 which is greater than the first width W1.

In the display device 600 according to another embodiment of the present disclosure, the second light scattering layer 182 in which a greater number of light scattering particles are dispersed than in the first light scattering layer 181 is disposed on the second LED ED2. Therefore, in the display device 600 according to another embodiment of the present disclosure, the luminance of the second area A2 in which the second LED ED2 is disposed can be improved, and, thus, the power consumption of the display device 600 can be reduced.

Further, in the display device 600 according to another embodiment of the present disclosure, the second light scattering layer 182 having a high viscosity is disposed in the second area A2 in which the second LED ED2 is disposed. Thus, it is possible to suppress the overflow and excessive coating of the second light scattering layer 182 onto the first area A1 of its adjacent sub-pixel SP.

Meanwhile, while a second LED is transferred onto a repair region, a contact failure can occur among a plurality of connection electrodes, a bonding layer, and the second LED. For example, a position of the second LED can be shifted due to a manufacturing process error. Thus, a contact area between first and second electrodes of the second LED and the bonding layer can decrease, and a resistance can increase. Therefore, power consumption can be increased, and lifetime can decrease.

Thus, in the display device 600 according to another embodiment of the present disclosure, the second LED ED2 having a greater width than that of the plurality of first LEDs ED1 is transferred onto the repair region. Therefore, the area of the first electrode 634 and the second electrode 635 in the second LED ED2 can be increased. Further, a contact area among the bonding layer BDL, the second and third connection electrodes CE2 and CE3, and the first and second electrodes 634 and 635 can be increased. Therefore, even when an error occurs during a transfer process of the second LED ED2, a contact area among the second LED ED2, the bonding layer BDL, and the second and third connection electrodes CE2 and CE3 can be secured. Thus, a contact failure and a resistance problem can be solved or addressed. Therefore, the display device 600 according to another embodiment of the present disclosure can be implemented as a display device which can be driven with low power consumption and has a long lifetime by suppressing a contact failure of the second LED ED2.

Further, in the display device 600 according to another embodiment of the present disclosure, the second LED ED2 having a greater width than that of the plurality of first LEDs ED1 is transferred onto the repair region. Therefore, an emission area of the second LED ED2 can be increased. For example, the emission layer 632 of the second LED ED2 can be greater in area than the emission layer 132 of the first LED ED1. Thus, the second LED ED2 can emit a greater amount of light than each of the plurality of first LEDs ED1. Therefore, even when the display device 600 is designed to improve light extraction of the plurality of first LEDs ED1, the emission area of the second LED ED2 can be increased. Thus, a great amount of light can be emitted from the second LED ED2.

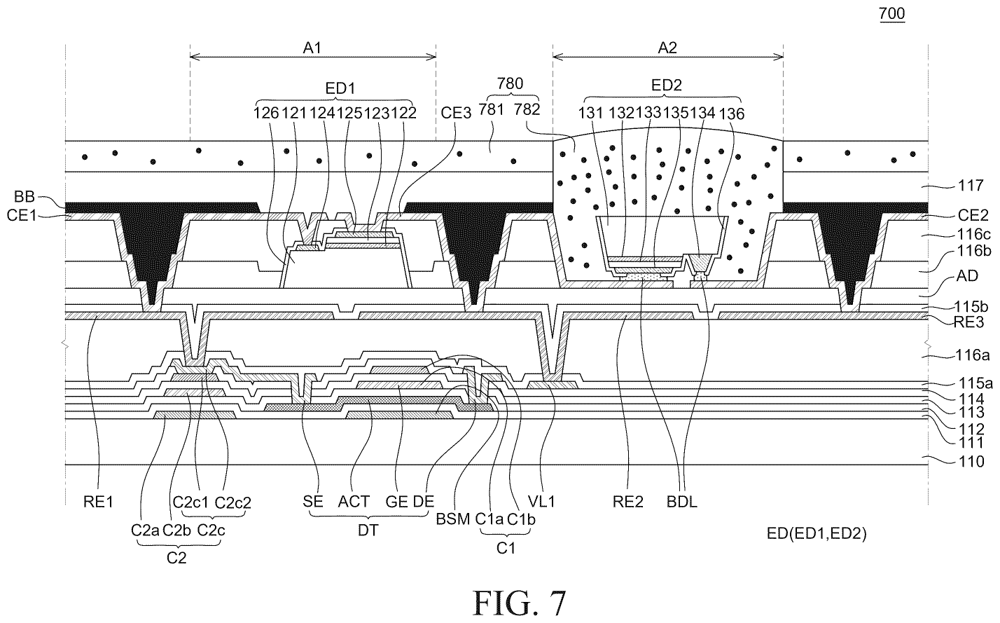

FIG. 7 is a cross-sectional view of a display device according to yet another embodiment of the present disclosure. A display device 700 shown in FIG. 7 is substantially the same as the display device 100 shown in FIG. 1 through FIG. 5, except a light scattering layer 780. Therefore, a redundant description will be omitted or may be briefly mentioned.

Referring to FIG. 7, the light scattering layer 780 is disposed on the plurality of LEDs ED.

The light scattering layer 780 includes the first light scattering layer 781 disposed on the plurality of first LEDs ED1 and a second light scattering layer 782 disposed on the second LED ED2.

The upper surface of the second light scattering layer 782 can protrude above the substrate 110. Thus, the upper surface of the second light scattering layer 782 can be inclined with respect to the substrate 110. For example, the upper surface of the second light scattering layer 782 can further protrude than an upper surface of the first light scattering layer 781 parallel with the substrate 110.

The second light scattering layer 782 protrude above the substrate 110, the second light scattering layer 782 can protrude below the substrate 110. However, the present disclosure is not limited thereto. The second light scattering layer 782 can have a plurality of corrugations.

In the display device 700 according to yet another embodiment of the present disclosure, the second light scattering layer 782 in which a greater number of light scattering particles are dispersed than in the first light scattering layer 781 is disposed on the second LED ED2. This is to improve a light extraction efficiency of the second LED ED2. Therefore, in the display device 700 according to yet another embodiment of the present disclosure, the luminance of the second area A2 in which the second LED ED2 is disposed can be improved, and, thus, the power consumption of the display device 700 can be reduced.

Further, in the display device 700 according to yet another embodiment of the present disclosure, the second light scattering layer 782 having a high viscosity is disposed in the second area A2 in which the second LED ED2 is disposed. Thus, it is possible to suppress the overflow and excessive coating of the second light scattering layer 782 onto the first area A1 of its adjacent sub-pixel SP.

In the display device 700 according to yet another embodiment of the present disclosure, the upper surface of the second light scattering layer 782 is inclined with respect to the substrate 110. Thus, light proceeding toward a side portion of the second LED ED2 can be refracted to the front direction. Therefore, it is possible to improve the light extraction efficiency of the second LED ED2 and also possible to reduce a variation depending on the viewing angle. Therefore, the display device 700 according to yet another embodiment of the present disclosure can have a long lifetime and require low power consumption.

Various embodiments of the present disclosure can also be described as follows:

According to an aspect of the present disclosure, there is provided a display device. The display device comprises a substrate in which a plurality of sub-pixels is defined. The display device comprises a plurality of reflective electrodes disposed on the substrate. The display device comprises a plurality of first light emitting diodes (LEDs) disposed on the plurality of reflective electrodes in each of the plurality of sub-pixels. The display device comprises a second LED disposed on the plurality of reflective electrodes in each of the plurality of sub-pixels and different from the plurality of first LEDs. The display device comprises a first light scattering layer disposed on the plurality of first LEDs. The display device comprises a second light scattering layer disposed on the second LED and separated from the first light scattering layer.

Each of the first light scattering layer and the second light scattering layer can contain an organic material in which light scattering particles are dispersed.

The number of light scattering particles dispersed in the second light scattering layer per unit area can be greater than the number of light scattering particles dispersed in the first light scattering layer per unit area.

The number of light scattering particles dispersed in the second light scattering layer per unit area can be greater by about 10% to about 20% than that of light scattering particles dispersed in the first light scattering layer per unit area.

The first light scattering layer can have a higher transmittance than the second light scattering layer.

The second light scattering layer can have a higher refractive index than the first light scattering layer.

The second light scattering layer can have a different viscosity from the first light scattering layer.

The second light scattering layer can have a higher viscosity than the first light scattering layer.

The first light scattering layer can contain a thermosetting material, and the second light scattering layer contains a UV-curable material.

The display device can further comprise a bank which defines the plurality of sub-pixels, wherein the first light scattering layer can be disposed on the bank so as to overlap the bank, and the second light scattering layer can be disposed so as not to overlap the bank.

The second light scattering layer can be in contact with a side surface of the bank and a side surface of the first light scattering layer.

The second LED is a normal LED, and one of the plurality of first LEDs disposed in the same sub-pixel as the second LED can be a defective LED.

Each of the plurality of first LEDs and the second LED can include a first semiconductor layer, a second semiconductor layer having a smaller width than that of the first semiconductor layer, an emission layer having a smaller width than that of the first semiconductor layer and disposed between the first semiconductor layer and the second semiconductor layer, a first electrode in contact with the first semiconductor layer and a second electrode in contact with the second semiconductor layer, wherein a lamination order of the first LED can be opposite to that of the second LED.

The display device can further comprise a plurality of connection electrodes disposed on the reflective electrode and connected to the reflective electrode, wherein the first light scattering layer can be disposed to be spaced apart from the plurality of connection electrodes, and the second light scattering layer can cover parts of upper surfaces of the plurality of connection electrodes.

The second LED can have a greater width than that of the plurality of first LEDs.

An upper surface of the first light scattering layer can be parallel with an upper surface of the substrate, and an upper surface of the second light scattering layer can be inclined with respect to the upper surface of the substrate.

Although various embodiments of the present disclosure have been described in detail with reference to the accompanying drawings, the present disclosure is not limited thereto and can be embodied in many different forms without departing from the technical concept of the present disclosure. Therefore, various embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate in which a plurality of sub-pixels is defined, each of the plurality of subpixel including a first area and second area;
a plurality of first light emitting diodes (LEDs) each disposed in the first area of the plurality of sub-pixels;
a second light emitting diode disposed in the second area of at least one of the plurality of sub-pixels, the second light emitting diode being different from the plurality of first light emitting diodes;
a first light scattering layer on the plurality of first light emitting diodes; and
a second light scattering layer on the second light emitting diode and having different properties from the first light scattering layer.

2. The display device according to claim 1, wherein each of the first light scattering layer and the second light scattering layer contains an organic material in which light scattering particles are dispersed.

3. The display device according to claim 2, wherein a number of light scattering particles dispersed in the second light scattering layer per unit area is greater than a number of light scattering particles dispersed in the first light scattering layer per unit area.

4. The display device according to claim 3, wherein the number of light scattering particles dispersed in the second light scattering layer per unit area is greater by about 10% to about 20% than the number of light scattering particles dispersed in the first light scattering layer per unit area.

5. The display device according to claim 1, wherein the first light scattering layer has a higher transmittance than the second light scattering layer.

6. The display device according to claim 1, wherein the second light scattering layer has a higher refractive index than the first light scattering layer.

7. The display device according to claim 1, wherein the second light scattering layer has a higher viscosity than the first light scattering layer.

8. The display device according to claim 1, wherein the first light scattering layer contains a thermosetting material, and the second light scattering layer contains an ultraviolet (UV)-curable material.

9. The display device according to claim 1, further comprising:
a bank which defines the plurality of sub-pixels,
wherein the first light scattering layer is disposed on the bank so as to overlap the bank, and
the second light scattering layer is disposed so as not to overlap the bank.

10. The display device according to claim 9, wherein the second light scattering layer is in contact with a side surface of the bank and a side surface of the first light scattering layer.

11. The display device according to claim 1, wherein the second light emitting diode is non-defective and the first light emitting diode in a same sub-pixel as the second light emitting diode is defective light emitting diode.

12. The display device according to claim 1, wherein each of the plurality of first light emitting diodes and the second light emitting diode includes:
a first semiconductor layer;
a second semiconductor layer having a smaller width than a width of the first semiconductor layer;
an emission layer having a smaller width than the width of the first semiconductor layer and disposed between the first semiconductor layer and the second semiconductor layer;
a first electrode in contact with the first semiconductor layer; and
a second electrode in contact with the second semiconductor layer,
wherein a lamination order of the first light emitting diode is opposite to a lamination order of the second light emitting diode.

13. The display device according to claim 1, further comprising:
a plurality of reflective electrodes disposed on the substrate,
wherein the plurality of the first light emitting diodes and the second light emitting diode are disposed on the plurality of reflective electrodes.

14. The display device according to claim 13, further comprising:
a plurality of connection electrodes on the plurality of reflective electrode connected to the reflective electrode,
wherein the first light scattering layer is spaced apart from the plurality of connection electrodes, and
the second light scattering layer covers parts of upper surfaces of the plurality of connection electrodes.

15. The display device according to claim 14, wherein the plurality of connection electrodes are disposed on the plurality of first light emitting diodes in the first area, and disposed below the second light emitting diode in the second area.

16. The display device according to claim 1, wherein the second light emitting diode has a greater width than the plurality of first light emitting diodes.

17. The display device according to claim 1, wherein an upper surface of the first light scattering layer is parallel with an upper surface of the substrate, and an upper surface of the second light scattering layer is inclined with respect to the upper surface of the substrate.

18. The display device according to claim 17, wherein the upper surface of the second light scattering layer has a plurality of corrugations.
